(19) United States
(12) Patent Application Publication
(10) Pub. No.: US 2026/0023957 A1
(43) Pub. Date: Jan. 22, 2026

(54) NEURAL NETWORK DEVICE AND OPERATION CONDITION DETERMINATION METHOD

(71) Applicant: TOHOKU UNIVERSITY, Miyagi (JP)

(72) Inventors: Tao LI, Miyagi (JP); Yitao MA, Miyagi (JP); Tetsuo ENDOH, Miyagi (JP)

(21) Appl. No.: 18/875,216

(22) PCT Filed: Mar. 29, 2024
(86) PCT No.: PCT/JP2024/013285

§ 371 Date: Mar. 18, 2025

(30) Foreign Application Priority Data
Mar. 30, 2023 (JP) 2023-055875

(51) Int. Cl. G06N 3/063; G11C 11/54

(52) U.S. Cl. CPC G06N 3/063; G11C 11/54

(57) ABSTRACT

Provided are a neural network device and an operating condition determination method capable of reducing power consumption. A neural network device 10 includes a processor 12, a power supply unit 14, and an operating condition determination unit 16. The processor 12 includes a logic operation circuit 21 and a memory 22, and performs, by a convolutional neural network, recognition processing on data to be processed. An output control circuit 32 of the power supply unit 14 adjusts a write current to a set value at which a recognition accuracy satisfies a preset set accuracy and that is set to be smaller than a specified value determined to switch bits in memory cells 24.

### TECHNICAL FIELD

The present invention relates to a neural network device and an operating condition determination method.

### BACKGROUND ART

Clock gating that stops supply of a clock to a circuit block not involved in operation and power gating that cuts off power supply are known as techniques for reducing power consumption of a semi-conductor circuit. Both techniques reduce power consumption by stopping the supply of clock and power when there is no need to operate the circuit block subject to gating.

In addition, various neural network devices have been proposed that perform, on a semi-conductor circuit, information processing that uses a mechanism of a brain of a living body as a model. Some of such neural network devices are known to perform clock gating and power gating (see, for example, Patent Literatures 1 and 2). Further, Patent Literature 3 proposes a neural network device that uses a parallel processor and parallel input processing, which reduce power consumption by optimizing a processing flow.

### CITATION LIST

### Non-Patent Literature

PTL 1: JP2019-46199A
PTL 3: US2021/0081773
PTL 2: US2018/0300615

### SUMMARY OF INVENTION

### Technical Problem

In the neural network device, the number of operations is very large, and the number of accesses to the memory is also very large. For this reason, a new technique, different from clock gating, power gating, and the like, which reduces power consumption is required.

The present invention has been made in view of the above circumstances, and an object thereof is to provide a neural network device and an operating condition determination method capable of reducing power consumption.

### Solution to Problem

A neural network device according to the present invention, including: a neural network operation unit including a memory that includes a plurality of memory cells and that holds operation data for neural network processing, and an operation circuit that transmits and receives the operation data to and from the memory and that performs operation in the neural network processing using the operation data; and a power supply unit configured to supply, to the memory when the operation data is written, a write current or a write voltage having a set value at which a processing accuracy of the neural network processing by the neural network operation unit is equal to or greater than a set accuracy and that is set to be smaller than a specified value determined to switch bits for the plurality of memory cells.

An operating condition determination method according to the present invention, including: an accuracy setting step of setting, as a set accuracy, a processing accuracy to be satisfied by a neural network operation unit including a memory that includes a plurality of memory cells and that holds operation data for neural network processing, and an operation circuit that transmits and receives the operation data to and from the memory and that performs operation in the neural network processing using the operation data; and a determination step of determining, for a write current or a write voltage supplied to the memory when the operation data is written to the memory, a set value that satisfies the set accuracy and that is set to be smaller than a specified value determined to switch bits for the plurality of memory cells.

### Advantageous Effects of Invention

According to the present invention, since a write current for operation data in neural network processing is set smaller than a specified value while maintaining a predetermined processing accuracy, power consumption of a neural network device can be reduced.

### BRIEF DESCRIPTION OF DRAWINGS

FIG. 1 is a block diagram illustrating a configuration of a neural network device according to a first embodiment.

FIG. 2 is a circuit diagram illustrating an example of a configuration of a memory cell.

FIG. 3 is a graph illustrating an example of a relation between a write current and a magnetization switching probability of an MTJ element provided in the memory cell.

FIG. 4 is a flowchart illustrating a procedure for determining a set value of the write current.

FIG. 5 is a graph illustrating an example of determining a set value when there is a variation in the relation between the write current and the magnetization switching probability of the MTJ element.

FIG. 6 is a graph illustrating an example of determining a set value when MTJ elements are connected in parallel to memory cells.

FIG. 7 is a block diagram illustrating a configuration of a neural network device according to a second embodiment.

FIG. 8 is a flowchart illustrating a procedure for determining a set value by stepwisely decreasing a write current.

FIG. 9 is a flowchart illustrating a procedure for determining a set value by reducing a write current, including a training mode.

FIG. 10 is a graph illustrating a result of simulating an influence of an error in operation data on a recognition accuracy of a neural network.

FIG. 11 is a graph illustrating a result of simulating, using another neural network model, the influence of the error in operation data on the recognition accuracy of the neural network.

### DESCRIPTION OF EMBODIMENTS

### First Embodiment

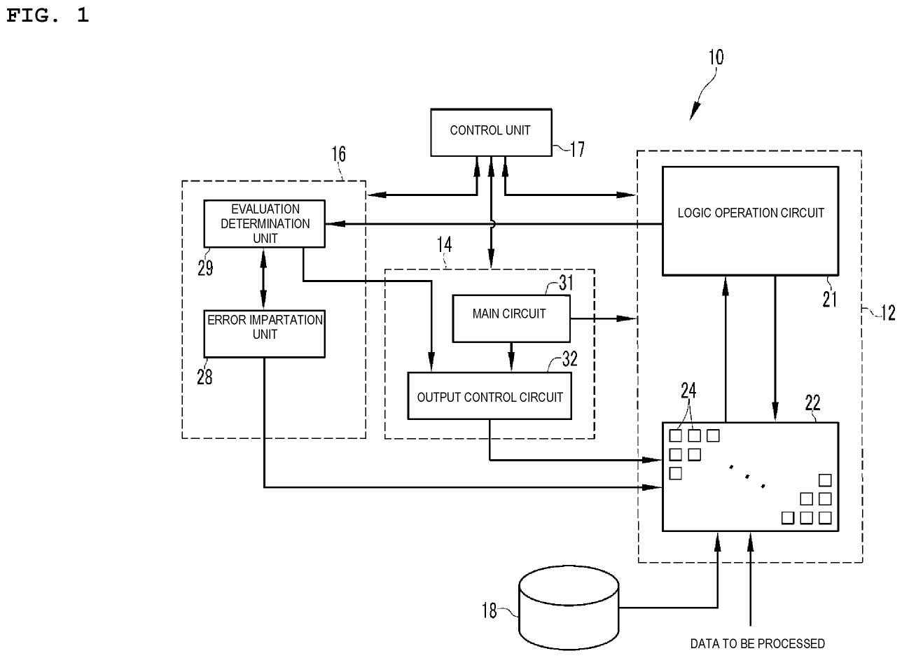

In FIG. 1, a neural network device 10 includes a processor 12 serving as a neural network operation unit, a power supply unit 14, an operating condition determination unit 16, a control unit 17 that collectively controls these units, and the like. The neural network device 10 performs neural network processing, by the processor 12, on data to be processed. The data to be processed includes a plurality of pieces of element data. In this example, the neural network processing is, for example, recognition processing for recognizing an object in an image. A target to be processed in this case is an image, image data thereof is input as data to be processed, and the element data is pixel data.

The neural network device 10 in this example focuses on the fact that there is almost no influence on a processing accuracy (recognition accuracy) of the neural network processing even if there is a loss in a part of data, and reduces power required for writing the data to a memory while ensuring a necessary processing accuracy by allowing a write error to occur at a degree of probability in writing to a memory cell. In this example, the recognition processing on an image or the like is described as an example of the neural network processing. However, the neural network processing is not limited to this.

The neural network device 10 includes a training mode, a recognition mode, and an operating condition determination mode. The training mode is a mode for performing machine learning, and optimizes a weight (also referred to as a parameter or the like) to be used in the recognition mode using a training dataset. The training dataset is, for example, a collection of a plurality of pieces of training data for which ground truth labels for recognition results are prepared. That is, in the training mode, the same recognition processing as in the recognition mode is performed using each training data in the training dataset as data to be processed, a weight is updated based on a recognition result, and the weight is determined to achieve a high recognition accuracy. In the recognition mode, recognition processing is performed on input recognition processing data using a weight optimized in the training mode, and a recognition result is output. The operating condition determination mode is a mode for determining a write current as described in detail later.

The training dataset used for the recognition processing is of the same type as the target to be processed. Therefore, when the target to be processed is an image, a training dataset in which the training data is image data is used, and the element data of the training data is pixel data. A test dataset, which will be described later, is similar to the training dataset and is a collection of a plurality of pieces of test data for which ground truth labels for recognition results are prepared, and each test data includes a plurality of pieces of element data.

In this example, the training dataset and the test dataset are respectively held in a storage 18. The data to be processed is input to the processor 12 in the recognition processing in the recognition mode. The storage 18 may be provided in the neural network device 10, or may be connected to the neural network device 10 when necessary.

The processor 12 includes a logic operation circuit 21 and a memory 22, and performs recognition processing on the data to be processed, by a neural network, in this example, a convolutional neural network (CNN). The logic operation circuit 21 includes a CPU, a multiplier, an adder, a register, and the like, and sequentially performs each operation in a convolution layer, a pooling layer, a fully-connected layer, and an output layer in the recognition processing. In the training mode, the processor 12 rewrites weight data on the memory 22, which is a weight used for each operation in the convolution layer and the fully-connected layer, based on a result of the recognition processing.

In this example, an architecture of the convolutional neural network performed by the processor 12 as described above is not limited to that described above. For example, operations in the fully-connected layer and the output layer may be performed after repeatedly executing operation processing in the convolution layer and the pooling layer a plurality of times. Further, the neural network processing by the processor 12 is not limited to the convolutional neural network, and may include, for example, operation processing such as that in a fully convolutional network (FCN) consisting of only convolution layers, or a deep neural network in which operations in a fully-connected layer are repeated a plurality of times. Further, as the architecture for the neural network processing performed by the processor 12, for example, a known SSD, YOLO, and TinyYOLO may be used.

For example, in an operation in the convolution layer, the logic operation circuit 21 reads out, from the memory 22, element data in an input layer, that is, element data of data to be processed and weight data of a convolutional filter, performs a convolution operation, and writes, to the memory 22, an operation result obtained by performing an operation using an activation function on a convolution operation result as element data in the convolution layer. The element data in the convolution layer is data of a feature map. Further, in an operation in the pooling layer, the logic operation circuit 21 reads out each element data in the convolution layer from the memory 22, and writes, to the memory 22, data extracted by, for example, maximum value pooling processing as element data in the pooling layer.

Further, in an operation in the fully-connected layer, the logic operation circuit 21 reads out the element data in the pooling layer and weight data in the fully-connected layer from the memory 22, and writes, to the memory 22, data obtained by performing an operation using the read data as element data in the fully-connected layer. In an operation in the output layer, the logic operation circuit 21 reads out the element data in the fully-connected layer from the memory 22, performs an operation using a predetermined activation function (for example, a softmax function) on the read element data, and outputs an operation result as a result of the recognition processing. In this example, as described above, the element data and the weight data used in the convolution layer, the pooling layer, the fully-connected layer, and the output layer are operation data.

Here, a collection of the element data in the convolution layer is referred to as convolution layer data, a collection of the element data in the pooling layer is referred to as pooling layer data, and the element data in the fully-connected layer is referred to as fully-connected layer data. A collection of the weight data in the convolution layer is referred to as a convolution layer weight dataset, and a collection of the weight data in the fully-connected layer is referred to as a fully-connected layer weight dataset. In the following description, the convolution layer data, the pooling layer data, and the fully-connected layer data are collectively referred to as layer data when there is no need to distinguish between them, and the convolution layer weight dataset and the fully-connected layer weight dataset are collectively referred to as a weight dataset when there is no need to distinguish between them.

The memory 22 includes a plurality of memory cells 24, and holds operation data in the recognition processing. That is, the logic operation circuit 21 transmits and receives operation data to and from the memory 22, and performs operation in the recognition processing using the operation data. The operation data held in the memory 22 is each element data and each weight data, and is the input layer data (data to be processed), the convolution layer data, the pooling layer data, the fully-connected layer data, the convolution layer weight dataset, and the fully-connected layer weight dataset. The weight dataset determined in the training mode is held in the storage 18, read from the storage 18, and written to the memory 22.

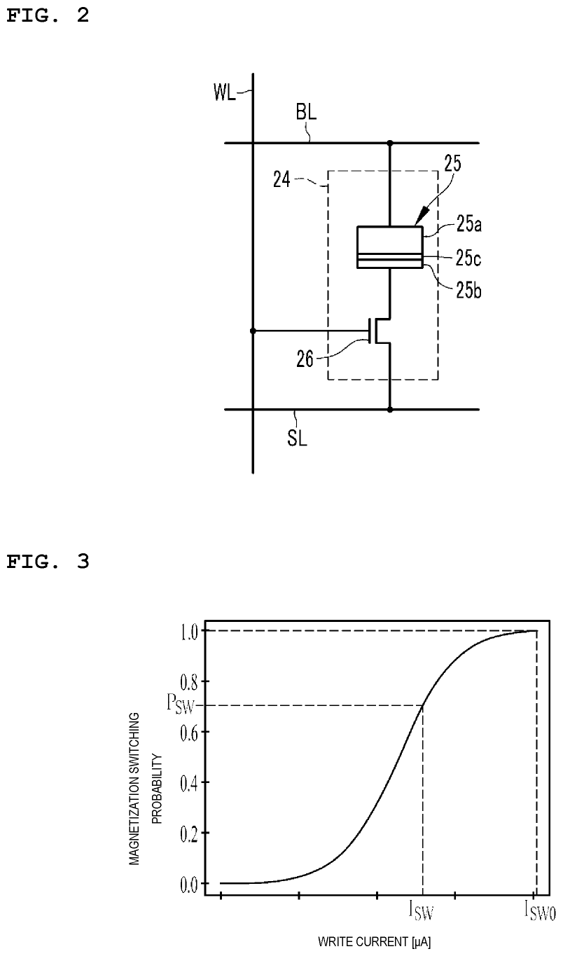

Each memory cell 24 stores one bit of data. Therefore, a plurality of bits of operation data are held by the plurality of memory cells 24. As illustrated in FIG. 2, the memory cell 24 in this example is of a 1T-1MTJ type including one magnetic tunnel junction (MTJ) element 25 that serves as a substantial storage element, and one select transistor 26. The MTJ element 25 has a structure in which a magnetization fixed layer 25a, whose magnetization direction is fixed, and a magnetization free layer 25b, whose magnetization direction can be changed, are stacked with an insulating film 25c interposed therebetween. The memory 22 is, for example, an STT-MRAM using a spin transfer torque (STT) type MTJ element 25. Therefore, the MTJ element 25 can change the magnetization direction of the magnetization free layer 25b by passing a write current therethrough, and the magnetization direction of the magnetization free layer 25b is determined by a direction of the write current. Although the memory cell 24 in this example is of the 1T-1MTJ type, a configuration of the memory cell 24 is not limited thereto, and may be a 1T-2MTJ type, a 2T-2MTJ type, or the like. When the 1T-1MTJ type or 2T-2MTJ type memory cells in which a write error is relatively likely to occur are used, power consumption can be more effectively reduced.

The MTJ element 25 is either in a parallel state in which the respective magnetization directions of the magnetization fixed layer 25a and the magnetization free layer 25b coincide with each other or in an antiparallel state in which the magnetization directions are opposite to each other. That is, by turning on the select transistor 26 via a word line WL and changing the direction of the write current supplied to the memory cell 24, in this example, the write current flowing through the MTJ element 25 between a bit line BL and a source line SL, the MTJ element 25 can be set to either the parallel state or the antiparallel state. Specifically, when the write current flows in a direction from the magnetization free layer 25b toward the magnetization fixed layer 25a, the MTJ element 25 is in the parallel state, and when the write current flows in the direction from the magnetization fixed layer 25a toward the magnetization free layer 25b, the MTJ element 25 is in the antiparallel state. The magnetization direction of the magnetization free layer 25b does not change even when the write current is cut off. That is, the memory 22 is a nonvolatile memory.

For example, as a value of a bit, one bit of data is associated with “1” in the parallel state of the MTJ element 25 and “0” in the antiparallel state of the MTJ element 25. Therefore, by inverting the magnetization direction of the magnetization free layer 25b, the value of the bit (“0” or “1”) held by the memory cell 24 is switched.

Under a condition that a time for which the write current flows is constant, a bit switching probability at which the value of the bit held by the memory cell 24 is rewritten, that is, a magnetization switching probability at which magnetization inversion of the magnetization free layer 25b occurs depends on a magnitude of the write current, and the magnetization switching probability increases as the write current increases. In this example, using the fact that the magnetization switching probability depends on the magnitude of the write current, the write error is allowed to occur at a degree of probability in the write of the memory cell 24 as described above, and thus the write current for the operation data in the recognition mode is reduced, and the power consumption is reduced.

The MTJ element 25 has a low electrical resistance in the parallel state and a high electrical resistance in the antiparallel state. When one bit held by the memory cell 24 is read out, the select transistor 26 is turned on, a read current to an extent that the magnetization free layer 25b does not perform magnetization inversion flows through the MTJ element 25, and a level of the electrical resistance of the MTJ element 25 is determined based on, for example, a current flowing through the bit line BL or a potential change in the bit line BL. On or off of the select transistor 26, control of the direction of the write current flowing through the MTJ element 25, and determination of the level of the electrical resistance of the MTJ element 25 are performed by a circuit (not illustrated) provided in the memory 22. The magnitude of the write current is controlled by the power supply unit 14.

In FIG. 1, the power supply unit 14 includes a main circuit 31 and an output control circuit 32, and supplies power for causing the processor 12 to operate. The main circuit 31 supplies a drive voltage for driving the logic operation circuit 21 and the select transistor 26 of the memory cell 24, and a read current for the memory cell 24. The output control circuit 32 includes, for example, a constant current circuit in which a magnitude of a current is variable, and supplies a write current to the memory cell 24.

The output control circuit 32 adjusts the write current to a set value I_{SW} that is set to be smaller than a specified value I_{SW0} determined to cause bit switching of the memory cell 24, that is, magnetization inversion of the magnetization free layer 25b of the MTJ element 25 to occur. The specified value I_{SW0} is determined as an electrical characteristic specification of the MTJ element 25, or is set such that the magnetization switching probability is theoretically approximately 100% (for example, 99% or more) in terms of design of a memory circuit based on the MTJ element 25. Therefore, the set value I_{SW} is, for example, a write current having a magnetization switching probability smaller than 99%. The set value I_{SW} of the write current is determined such that a recognition accuracy of recognition processing by the processor 12 satisfies a preset set accuracy M_{A0}.

In this example, since the MTJ element 25 having two states corresponding to one bit is described, the specified value I_{SW0} is set as a write current that flips a bit. However, the specified value I_{SW0} can be used as a specified value of a write current that inverts a state of a nonvolatile storage element (bit inversion), which has two states, other than the above MTJ element 25, and can be used as a specified value that is set as a write current that transitions between respective states in a nonvolatile storage element having multi-state (multi-value). The same applies to the specified value I_{SW0} when a volatile storage element is used.

Further, when it is assumed that the write current to the memory cell 24 is driven at a set value I_{SW} smaller than the specified value I_{SW0}, the select transistor 26 can be reduced in size, which is advantageous for high integration of the memory 22 and therefore the processor 12. As a result, speeds of the memory 22 and the processor 12 are advantageously increased.

In the neural network device 10, the power consumption is reduced by setting the write current to the memory cell 24 to be smaller than the specified value I_{SW0} as described above, and therefore clock gating and power gating can be further applied to further reduce the power consumption. For example, when the logic operation circuit 21 does not access the memory 22, supply of a clock to the memory 22 can be stopped or supply of power can be cut off. Of course, the clock gating and the power gating can also be performed on the logic operation circuit 21.

In the operating condition determination mode, the operating condition determination unit 16 determines a set value I_{SW} of a write current at which a recognition accuracy satisfies the preset set accuracy M_{A0} and that is smaller than the specified value I_{SW0}. When determining the set value I_{SW}, the operating condition determination unit 16 causes the processor 12 to operate via the control unit 17, imparts an error to the operation data held in the memory 22 to execute recognition processing on the test dataset, evaluates a recognition accuracy thereof, and determines the set value I_{SW}. One recognition processing on the test dataset is recognition processing on each test data that constitutes the test dataset. The operating condition determination unit 16 includes an error impartation unit 28 that imparts an error to the operation data, and an evaluation determination unit 29 that determines a set value I_{SW} of a write current based on an effective bit ratio P_{FT} described in detail later.

When the number of all bits of the operation data held in the memory 22 in one recognition processing on the test data is set as a total bit number N_{A}, and the number of bits that are not erroneous in the operation data held in the memory 22 in one recognition processing on the test data is set as an effective bit number N_{S} (hereinafter, referred to as effective bits), a ratio of the effective bit number N_{S} to the total bit number N_{A} is an effective bit ratio P_{FT} (=N_{S}/N_{A}).

If the number of bits of errors contained in the operation data to the total bit number N_{A} of the operation data, that is, the number of flipped bits (hereinafter, referred to as error bits) is set as an error bit number N_{E}, the effective bit ratio P_{FT} is expressed as “P_{FT}=(N_{A}−N_{E})/N_{A}”, and if a ratio of the error bit number N_{E} to the total bit number N_{A} is set as an error ratio R_{E} (=N_{E}/N_{A}), a relation between the effective bit ratio P_{FT} and the error ratio R_{E} is expressed as P_{FT}=1−R_{E}.

In this example, the operation data held in the memory 22 is the data to be processed (test data), the convolution layer data, the pooling layer data, the fully-connected layer data, the convolution layer weight dataset, and the fully-connected layer weight dataset, and a sum of the number of bits of these is the total bit number N_{A}.

The error impartation unit 28 imparts an error to a part of the operation data held in the memory 22. In this example, the error impartation unit 28 imparts an error to a part of the convolution layer weight dataset and the fully-connected layer weight dataset. That is, in this example, values of some bits of the convolution layer weight dataset and the fully-connected layer weight dataset are switched by the error bit number N_{E}.

The data to which an error is imparted is not limited to the above, and may be any of the operation data stored in memory 22, in this example, the test data, the convolution layer data, the pooling layer data, the fully-connected layer data, the convolution layer weight dataset, and the fully-connected layer weight dataset, or a combination of some of them or all of them. When an error is imparted to the layer data, for example, the error impartation unit 28 may impart an error at a step in which the layer data to which an error is imparted is written to the memory 22 during the recognition processing.

The error to the operation data is preferably randomly imparted. Further, in the operation data held in the memory 22, an error may be imparted by randomly selecting and switching individual bits of the weight data and the element data, or an error may be imparted to bits of the weight data and the element data by changing values of the data. Further, as a method of imparting an error, for example, a method such as random quantization, random bit-flip random pruning can be used.

The error impartation unit 28 keeps the error bit number N_{E} in the operation data for each test data in one recognition processing on the test dataset the same, and stepwisely changes the error bit number N_{E} for each recognition processing on the test dataset. In this example, the error impartation unit 28 stepwisely increases the error bit number N_{E} until the recognition accuracy is smaller than the set accuracy M_{A0}. That is, the effective bit ratio P_{FT} is stepwisely decreased until the recognition accuracy is smaller than the set accuracy M_{A0}.

The evaluation determination unit 29 receives a recognition result from the logic operation circuit 21. The evaluation determination unit 29 obtains a recognition accuracy for each test dataset, that is, the effective bit ratio P_{FT} based on a recognition result and a ground truth label for each test data in the test dataset. For the recognition accuracy, for example, an evaluation index such as mean average precision (mAP) can be used.

The evaluation determination unit 29 determines a set value I_{SW} of a write current using an effective bit ratio P_{FT} corresponding to a largest error bit number N_{E} among the error bit numbers N_{E} for which the recognition accuracy is larger than the set accuracy M_{A0}. Specifically, when the recognition processing is performed on the test dataset while stepwisely increasing the error bit number N_{E}, an effective bit ratio P_{FT} corresponding to an error bit number N_{E} immediately before the recognition accuracy falls below the set accuracy M_{A0} is identified, and the set value I_{SW} of the write current is determined based on the identified effective bit ratio P_{FT}.

The evaluation determination unit 29 converts the effective bit ratio P_{FT} identified as described above into the set value I_{SW} of the write current based on characteristics of the memory cell 24. The characteristics of the memory cell 24 in this example can be regarded as the same as characteristics of the MTJ element 25. The evaluation determination unit 29 sets the identified effective bit ratio P_{FT} as a magnetization switching probability P_{SW} at which the magnetization direction of the magnetization free layer 25b of the MTJ element 25 is switched, and sets, based on the characteristics of the MTJ element 25, a write current that results in the magnetization switching probability P_{SW} as the set value I_{SW}. The evaluation determination unit 29 sets the set value I_{SW} determined in this manner as the output control circuit 32.

FIG. 3 illustrates an example of a relation between a write current and a magnetization switching probability of the MTJ element 25. The MTJ element 25 exhibits an S-shaped characteristic in which the magnetization switching probability gradually increases as the write current increases, the magnetization switching probability increases in proportion to an increase of the write current when the write current exceeds a value, and when the magnetization switching probability approaches “1.0”, an increase rate of the magnetization switching probability decreases with respect to the increase of the write current. Based on such a characteristic of the MTJ element 25, the write current corresponding to the magnetization switching probability P_{SW} equal to the effective bit ratio P_{FT} is set as a set value I_{SW}.

In this example, after the machine learning in the training mode, that is, after the weight dataset is determined, the operating condition determination unit 16 causes the processor 12 to operate to perform the recognition processing on the test dataset, and sets the obtained recognition accuracy as a set accuracy M_{A0}. The machine learning in the training mode and the recognition processing on the test dataset are executed by setting a write current to a specified value I_{SW0}. Therefore, in this example, a write current that satisfies a maximum recognition accuracy is set as a set value I_{SW}.

A method of setting the set accuracy M_{A0} is not limited thereto. For example, the set accuracy M_{A0} may be set as desired. The set accuracy M_{A0} may be set according to a required recognition accuracy, a degree of power saving, or the like.

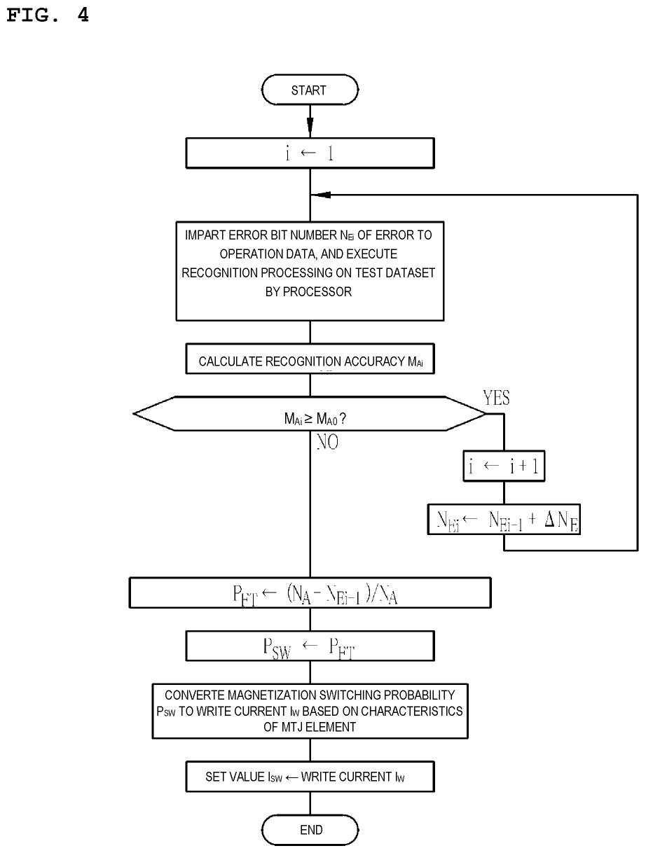

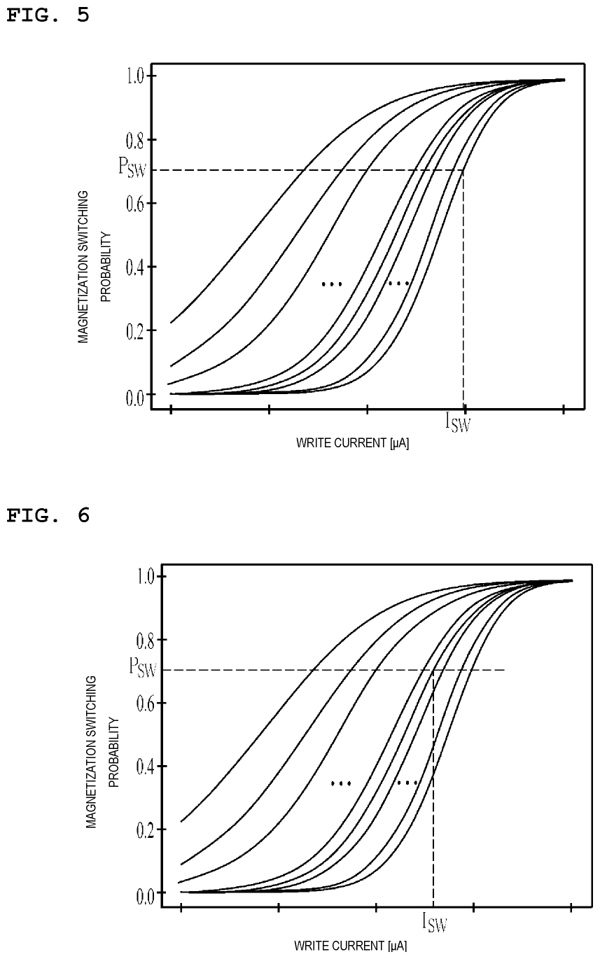

Next, effects of the above configuration will be described. First, a case in which a set value I_{SW} of a write current is determined in the operating condition determination mode will be described with reference to FIG. 4. In the operating condition determination mode in this example, a write current to the memory 22 is set to a specified value I_{SW0}.

For the operating condition determination mode, the operating condition determination mode does not always need to be executed prior to the recognition mode, and may be executed, for example, when the set value I_{SW} of the write current changes. For example, when the processor 12 changes the architecture for the neural network processing, it is preferable to execute the processing every time machine learning is performed in the training mode. Further, assuming that characteristics of the memory 22 change over time, the operating condition determination mode may be executed every time a predetermined time elapses or every time recognition processing are performed a predetermined number of times in the recognition mode. Furthermore, the operating condition determination mode may be executed every time the neural network device 10 is activated.

First recognition processing is performed on the test dataset. First, the convolution layer weight dataset and the fully-connected layer weight dataset determined using the machine learning in the training mode and the test dataset are read from the storage 18 and written to the memory 22. In the error impartation unit 28, the error bit number N_{E} is set to a first error bit number N_{E1}, which is an initial value. In this example, the error bit number Ni is selected to be a value at which the recognition accuracy is equal to or greater than the set accuracy M_{A0}. For the convolution layer weight dataset and the fully-connected layer weight dataset held in the memory 22, the error impartation unit 28 randomly selects, for example, the first error bit number N_{E1} of bits of these weight data, and gives an error by switching values of the selected bits.

After the error is imparted as described above, recognition processing is performed on the test dataset from the storage 18. First, first test data is read, written to the memory 22, and held as input layer data. Thereafter, the logic operation circuit 21 sequentially reads out element data in a first input layer (test data) and weight data in the convolution layer from the memory 22, and performs an operation in the convolution layer using the element data and the weight data. Element data in the convolution layer obtained by the operation in the convolution layer is sequentially written in the memory 22.

When all operations in the convolution layer complete, the logic operation circuit 21 sequentially reads out the element data in the convolution layer from the memory 22 and performs an operation in the pooling layer. For example, data extracted by maximum value pooling processing is written to the memory 22 as element data in the pooling layer. After the operation in the pooling layer, the logic operation circuit 21 sequentially reads out the element data in the pooling layer and the weight data in the fully-connected layer, and the operation in the fully-connected layer is performed using the read data. The data obtained by this operation is written to the memory 22 as element data in the fully-connected layer.

After the operation in the fully-connected layer, the element data in the fully-connected layer is read out from the memory 22, an operation using, for example, the softmax function is performed by the logic operation circuit 21, and an operation result thereof is output as a result of the recognition processing. In the operating condition determination mode, the result of the recognition processing is input from the logic operation circuit 21 to the evaluation determination unit 29.

The evaluation determination unit 29 collates the result of the recognition processing on the first test data input from the logic operation circuit 21 with a ground truth label for the first test data acquired from the storage 18, and determines whether the result of the recognition processing is correct or incorrect.

After the recognition processing is performed on the first test data as described above, second test data is read out from the storage 18 and recognition processing is performed in the same manner. When the recognition processing on the second test data is input from the logic operation circuit 21, the evaluation determination unit 29 collates a result of the recognition processing with a ground truth label for the second test data, and determines whether the result of the recognition processing is correct or incorrect. Also for third and subsequent test data, recognition processing is performed in the same manner as described above, a result of the recognition processing is collated with a corresponding ground truth label, and it is determined whether the result of the recognition processing is correct or incorrect.

After collating a result of recognition processing on final test data with a ground truth label, a recognition accuracy M_{A1} is obtained based on a recognition result of each test data in the test dataset. The evaluation determination unit 29 determines whether the recognition accuracy M_{A1} is equal to or greater than the set accuracy M_{A0}.

For example, when the recognition accuracy M_{A1} is equal to or greater than the set accuracy M_{A0}, the error bit number N_{E} is increased by one step, and second recognition processing is performed on the test dataset.

In the second recognition processing, the convolution layer weight dataset and the fully-connected layer weight dataset are read out from the storage 18 and written to the memory 22. Then, a second error bit number N_{E2} of bits of the convolution layer weight dataset and the fully-connected layer weight dataset held in the memory 22 are randomly selected, and the selected bits are switched. After an error is imparted as described above, recognition processing on the test dataset is performed in the same manner as in the first recognition processing.

The evaluation determination unit 29 determines whether a recognition accuracy M_{A2} obtained in second recognition processing is equal to or greater than the set accuracy M_{A0}. For example, when the recognition accuracy M_{A2} is equal to or greater than the set accuracy M_{A0}, the error bit number N_{E} is further increased by one step, and third recognition processing on the test dataset is performed. Thereafter, similarly, the recognition processing on the test dataset is performed until a recognition accuracy M_{Ai} (i is 1, 2, 3 . . . ) is smaller than the set accuracy M_{A0} while the error bit number N_{E} is stepwisely increased.

When the recognition accuracy M_{Ai} is first smaller than the set accuracy M_{A0}, the recognition processing on the test dataset ends, and the evaluation determination unit 29 determines a set value I_{SW} of a write current using the error bit number N_{E} used in the immediately preceding recognition processing.

For example, when a recognition accuracy M_{Ak} of k-th recognition processing is equal to or greater than the set accuracy M_{A0} and a recognition accuracy M_{Ak+1} of next (k+1)-th recognition processing is smaller than the set accuracy M_{A0}, a set value I_{SW} is determined using an error bit number N_{Ek} used in the k-th recognition processing. From the above relation between the effective bit ratio P_{FT}, the total bit number N_{A} of the operation data, and the error bit number N_{E}, the evaluation determination unit 29 obtains an effective bit ratio P_{FT} corresponding to the error bit number N_{Ek} as “P_{FT}=(N_{A}−N_{Ek})/N_{A}”. Then, the effective bit ratio P_{FT} is set as a magnetization switching probability P_{SW} of the MTJ element 25, and a write current I_{W} at which the magnetization switching probability P_{SW} is set as the set value I_{SW} based on the characteristics of the MTJ element 25.

Although the error bit number N_{E} is stepwisely increased in the above example, the error bit number N_{E} may be stepwisely decreased. In this case, as the error bit number N_{E1}, a value at which the recognition accuracy is smaller than the set accuracy M_{A0} is selected, and a set value I_{SW} may be determined in the same manner as described above based on an error bit number N_{E1} when a recognition accuracy M_{Ai} is first equal to or greater than the set accuracy M_{A0}.

Next, the recognition mode will be described. Before the recognition processing in the recognition mode, the convolution layer weight dataset and the fully-connected layer weight dataset are read out from the storage 18 and written to the memory 22. In this example, when the convolution layer weight dataset and the fully-connected layer weight dataset are written, the write current is set to the specified value I_{SW0}. However, the write current may be set as the set value I_{SW}. Further, the set value I_{SW} determined by the evaluation determination unit 29 as described above is set in the output control circuit 32. Since the memory 22 is nonvolatile, once the convolution layer weight dataset and the fully-connected layer weight dataset are written, there is no need to write them again unless there is a change in the convolution layer weight dataset and the fully-connected layer weight dataset.

The data to be processed that is to be recognized is written to the memory 22 and held as input layer data. When the data to be processed is written to the memory 22, the logic operation circuit 21 sequentially reads out element data in the input layer (data to be processed) and weight data in the convolution layer from the memory 22, performs an operation in the convolution layer, and sequentially writes, to the memory 22, the obtained element data in the convolution layer. After the operation in the convolution layer, the logic operation circuit 21 sequentially reads out element data in the convolution layer from the memory 22, performs an operation in the pooling layer, and writes, to the memory 22, the element data extracted by the maximum value pooling processing as element data in the pooling layer. Subsequently, the logic operation circuit 21 sequentially reads out the element data in the pooling layer and weight data in the fully-connected layer, and writes, to the memory 22, data obtained by performing an operation in the fully-connected layer as element data in the fully-connected layer. Then, after the operation in the fully-connected layer, the logic operation circuit 21 reads out the element data in the fully-connected layer from the memory 22, performs an operation using the softmax function, and outputs a result thereof as a result of recognition processing on the input data to be processed.

As described above, the recognition processing is performed on the data to be processed. When the element data in the input layer, the element data in the convolution layer, the element data in the pooling layer, and the element data in the fully-connected layer are written to the memory 22, a write current flows through each memory cell 24 to which the element data is to be written. At this time, a write current in a direction corresponding to a value of a bit of data to be held flows through each MTJ element 25 of the memory cell 24.

Here, when the write current is the specified value I_{SW0}, the write current flows, so that the magnetization direction of the magnetization free layer 25b of the MTJ element 25 of each memory cell 24 to be written corresponds to the direction of the write current. For example, when a value of the held bit is “0” and a value of a bit to be written is “1”, a write current in a direction from the magnetization fixed layer 25a to the magnetization free layer 25b flows through the MTJ element 25 in the antiparallel state. Accordingly, the magnetization direction of the magnetization free layer 25b is switched, the MTJ element 25 is in the parallel state, and the held bit is rewritten from “0” to “1”. Conversely, when the value of the held bit is “1” and the value of the bit to be written is “0”, a write current in a direction from the magnetization free layer 25b to the magnetization fixed layer 25a flows through the MTJ element 25 in the parallel state. Accordingly, the magnetization direction of the magnetization free layer 25b is switched, the MTJ element 25 is in the antiparallel state, and the value of the held bit is rewritten from “1” to “0”. When the value of the held bit is the same as the value of the bit to be written, the magnetization direction of the magnetization free layer 25b is not switched.

Incidentally, in the memory 22 of the processor 12, the output control circuit 32 causes a write current having a set value I_{SW} smaller than the specified value I_{SW0} to flow when the element data is written. Therefore, a probability of rewriting the value of the held bit as described above is a magnitude of the write current, that is, a magnetization switching probability P_{SW} for the set value I_{SW}. In other words, the value of the bit is not rewritten with a probability (1−P_{SW}) corresponding to the set value I_{SW}. In this case, the bit is an error bit when the previously held value differs from a value to be rewritten, and the bit is not an error bit when the held value and the value to be rewritten are the same.

Since the magnetization switching probability P_{SW} is the same value as the effective bit ratio P_{FT} when the set value I_{SW} is determined, an actual ratio of an actual effective bit number N_{S} to the total bit number N_{A} of the operation data written in the memory 22 as described above is equal to or greater than the effective bit ratio P_{FT}. As a result, the recognition processing on the data to be processed is performed while securing at least the set accuracy M_{A0} as the recognition accuracy.

As described above, when the element data is written, the write current having the set value I_{SW} smaller than the specified value I_{SW0} flows. Therefore, the power consumption when data is written to the memory 22 is reduced.

When Tiny YOLOV3 is used as the architecture for neural network processing by the processor 12, the effective bit ratio P_{FT} when the processing accuracy is a maximum processing accuracy is “0.7”, the specified value I_{SW0} is 270 μA, the set value I_{SW} can be set to 256 μA, and a reduction in the power consumption of 14 μA is confirmed.

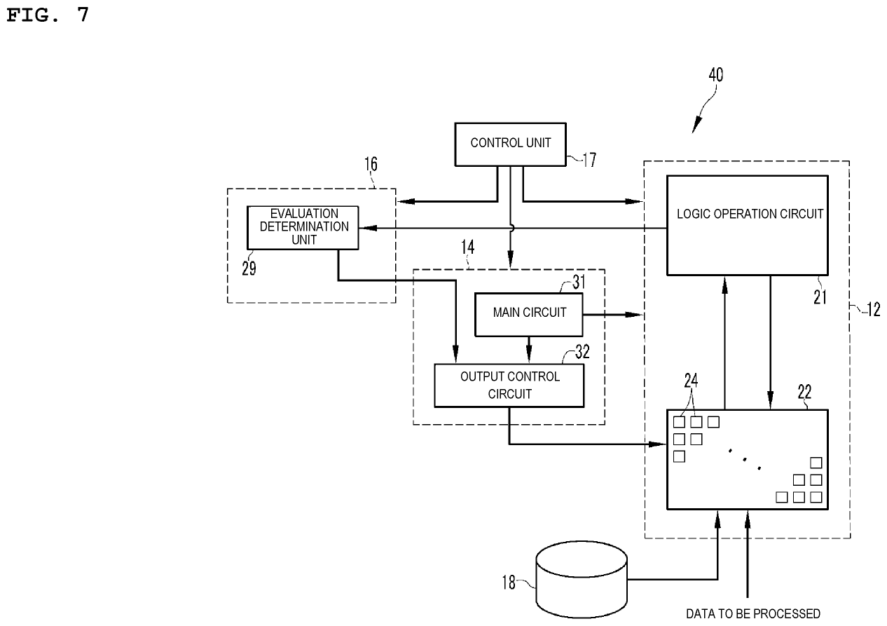

The characteristics of the memory cell 24, in this example, the MTJ element 25 may vary due to process variations or the like. In such a case, as illustrated in FIG. 5, it is preferable to convert the magnetization switching probability P_{SW} into the set value I_{SW} of the write current based on a characteristic with a highest write current for a magnetization switching probability P_{SW} of a conversion source among the characteristics of the respective memory cells 24 that constitute the memory 22. When the memory cell 24 includes a configuration in which a plurality of MTJ elements 25 are connected in parallel, even if the characteristics of the MTJ elements 25 vary, the memory cell 24 can be regarded as including an MTJ element having an average characteristic. Therefore, in such a case, as illustrated in FIG. 6, the magnetization switching probability P_{SW} can be converted into the set value I_{SW} of the write current based on the averaged characteristic of the MTJ element.

### Second Embodiment

In a second embodiment, a set value of a write current is determined by stepwisely changing the write current in the operating condition determination mode. The second embodiment is the same as the first embodiment except that the set value of the write current is determined by stepwisely changing the write current. The same components as those of the first embodiment are denoted by the same reference numerals, and detailed description thereof is omitted.

As illustrated in FIG. 7, a neural network device 40 in this example has the same configuration as that of the neural network device 10 according to the first embodiment except that the error impartation unit is omitted. In the operating condition determination mode, the operating condition determination unit 16 of the neural network device 40 causes the processor 12 to operate via the control unit 17 to execute recognition processing on the test dataset, and stepwisely changes the write current by the output control circuit 32 for each recognition processing on the test dataset, thereby setting a minimum write current that satisfies the set accuracy M_{A0} to the set value I_{SW}. In this example, the write current is stepwisely decreased for each recognition processing on the test dataset.

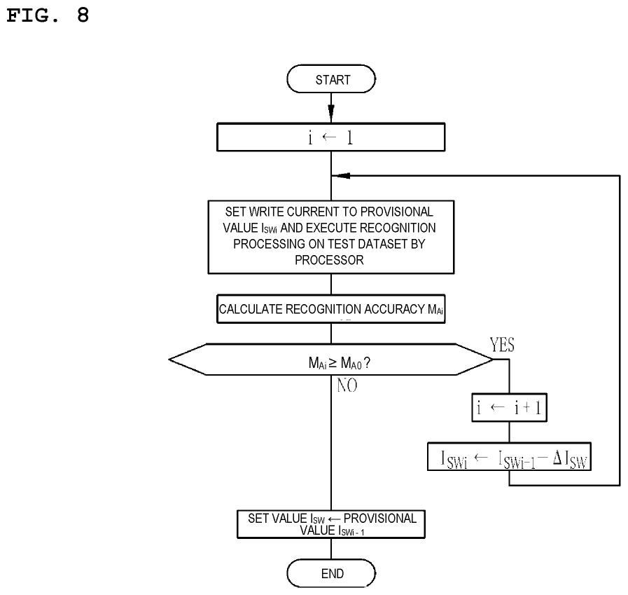

In the operating condition determination mode, as illustrated in FIG. 8, first, the write current is set to a provisional value I_{SW1} in first recognition processing, the recognition processing is performed on the test dataset, and a recognition accuracy M_{A1} is obtained. In this example, the provisional value I_{SW1} of the write current is selected to be a value at which the recognition accuracy is greater than the set accuracy M_{A0}. Then, the evaluation determination unit 29 determines whether the recognition accuracy M_{Ai} is equal to or greater than the set accuracy M_{A0}. For example, when the recognition accuracy M_{Ai} is equal to or greater than the set accuracy M_{A0}, the write current is set to a provisional value I_{SW2}, which is decreased one step, second recognition processing is performed on the test dataset, and it is determined whether the recognition accuracy M_{A2} is equal to or greater than the set accuracy M_{A0}.

When the write current (provisional value I_{SWi}) is stepwisely changed, it is also preferable to increase or decrease the write current to change the magnetization switching probability every constant value based on a relation between a write current and a magnetization switching probability of an element that constitutes the memory cell 24. For example, when the memory cell 24 includes the STT type MTJ element 25 as described above, the write current is increased or decreased to stepwisely change the magnetization switching probability every constant value based on the relation between the write current and the magnetization switching probability as illustrated in FIG. 3. At this time, an amount of change in the magnetization switching probability is preferably within a range of 95% or less and 5% or more, more preferably within a range of 70% or less and 30% or more, and particularly preferably within a range of 55% or less and 45% or more.

In this way, the recognition processing on the test dataset is performed by stepwisely decreasing the write current until the recognition accuracy M_{Ai} is smaller than the set accuracy M_{A0}. When the recognition accuracy M_{Ai} is first smaller than the set accuracy M_{A0}, the recognition processing on the test dataset ends, and a provisional value I_{SWi-1} used in the immediately preceding recognition processing is set as the set value I_{SW} of the write current.

In this example, in the operating condition determination mode, each recognition processing on the test dataset is performed in a state in which the weight dataset is written in advance to the memory 22 using a write current having a specified value I_{SW0}. However, the weight dataset may also be written to the memory 22 using a write current having a provisional value I_{SW1} for each recognition processing on the test dataset.

In the recognition mode, the write current having the set value I_{SW} determined as described above is supplied to the memory 22 to write operation data. As in the first embodiment, since the write current having the set value I_{SW} smaller than the specified value I_{SW0} flows, the power consumption when data is written to the memory 22 is reduced. Moreover, the recognition processing on the data to be processed is performed while securing at least the set accuracy M_{A0} as the recognition accuracy.

In this example, the write current is stepwisely decreased. However, the write current may be stepwisely increased. In this case, as the provisional value I_{SW1} of the write current, a value at which the recognition accuracy is smaller than the set accuracy M_{A0} is selected, and a set value I_{SW} may be determined based on the provisional value I_{SW1} when the recognition accuracy M_{Ai} is first equal to or greater than the set accuracy M_{A0}.

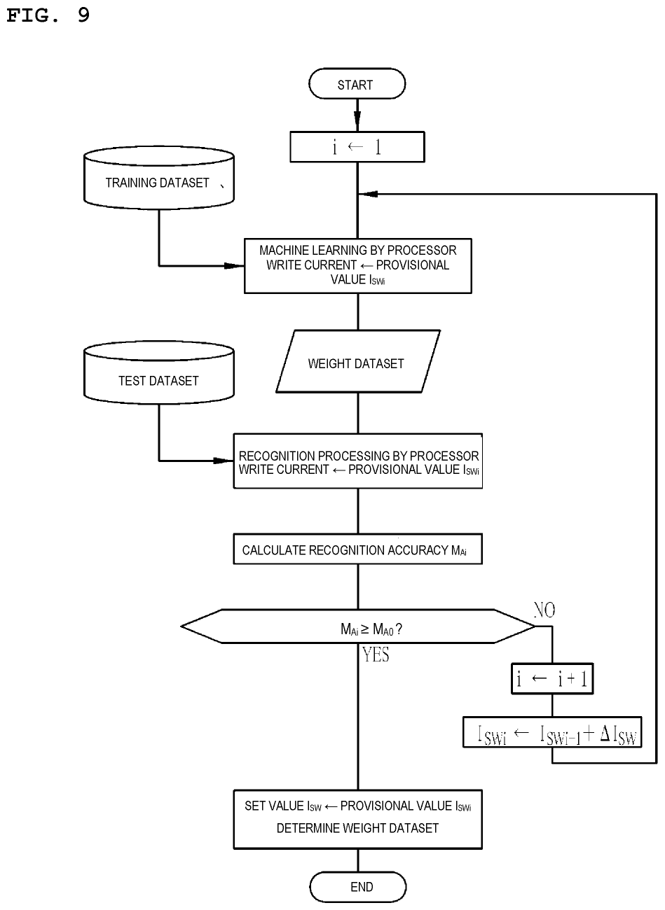

The operating condition determination mode in each of the above embodiments uses the weight dataset determined by the machine learning executed by setting the write current to the specified value I_{SW0}. However, as illustrated in an example of a procedure in FIG. 9, the weight dataset and the set value I_{SW} of the write current are determined by machine learning in a manner in which the write current is stepwisely changed.

In the example illustrated in FIG. 9, after the write current to the memory 22 is set to a provisional value I_{SW1} at which the recognition accuracy is smaller than the set accuracy M_{A0}, the processor 12 performs machine learning using the training dataset and optimizes the weight dataset held in the memory 22. Since the weight data in the memory 22 is rewritten (written) when the weight dataset is optimized by the machine learning, the weight dataset includes an error bit with a probability corresponding to the write current.

Subsequently, the processor 12 performs recognition processing on the test dataset using the weight dataset in the memory 22 optimized as described above. Also in this recognition processing, the element data is written by the write current having the provisional value I_{SWi}. Then, it is determined whether the recognition accuracy M_{A1} in this recognition processing is equal to or greater than the set accuracy M_{A0}. The set accuracy M_{A0} may be set as desired, and for example, may be a maximum recognition accuracy corresponding to an architecture for the recognition processing when the recognition processing is performed on the test dataset.

For example, when the recognition accuracy M_{A1} is smaller than the set accuracy M_{A0}, the write current is set to the provisional value I_{SW2}, which is increased by one step, machine learning using the training dataset and recognition processing on the test dataset using the weight dataset optimized by the machine learning are performed in the same manner as described above, and it is determined whether the recognition accuracy M_{A2} is equal to or larger than the set accuracy M_{A0}.

In this way, machine learning using the training dataset and recognition processing on the test dataset using the weight dataset optimized by the machine learning are performed until the recognition accuracy M_{Ai} is equal to or greater than the set accuracy M_{A0}. Then, when the recognition accuracy M_{Ai} is first equal to or greater than the set accuracy M_{A0}, the recognition processing on the test dataset ends, the provisional value I_{SWi} at that time is set as the set value I_{SW} of the write current, and the weight dataset is determined to be used in the recognition mode.

Although the write current is stepwisely increased in the example in FIG. 9, the write current may be stepwisely decreased as in the second embodiment. Although the write current is stepwisely changed in this example, the error bit number of the operation data may be stepwisely changed, that is, the effective bit ratio P_{FT} may be stepwisely changed to perform machine learning and determination of the set value I_{SW} of the write current as in the first embodiment.

The write current in only some of the layers, such as the input layer, the output layer, and intermediate layers (hidden layers) between the input layer and the output layer, such as the convolution layer and the fully-connected layer, can be set to a set value smaller than the specified value. Further, for example, the write current can be set to a set value smaller than the specified value for the convolution layer in which the weight data is large and the number of operations is the largest. For example, when the write current in only the convolution layer in the above example is made smaller than the specified value, in the operating condition determination mode, the set value of the write current may be determined by stepwisely changing the write current when the convolution layer weight dataset used in the operation in the convolution layer and the element data obtained by the operation are written. When the set value of the write current is determined by imparting an error, an error may be imparted to one or both of the convolution layer weight dataset used in the operation in the convolution layer and the convolution layer data obtained by the operation, and the set value of the write current may be determined based on the effective bit ratio P_{FT} obtained from the total bit number N_{A} and the effective bit number N_{S} of the convolution layer weight dataset and the convolution layer data.

The memory 22 in the above example is an STT-MRAM including the memory cell 24 using an STT type MTJ element that performs writing, that is, switching of a value of a bit by a current. However, the memory is not limited to this, and may be one in which memory cells are formed of storage elements in which a probability of switching a value of a bit changes according to a magnitude of a write current or a write voltage. When the memory element (memory cell) is configured to rewrite the held value of the bit by application of a write voltage, the write voltage that satisfies the set accuracy may be determined instead of the write current, and data may be written using the write voltage. For example, the memory may be an SOT-MRAM including a memory cell using a spin orbit torque (SOT) type MTJ element in which a value of a bit is switched by application of a write voltage, or a resistance change memory (ReRAM) in which a resistance is changed by application of a write voltage or a write current. The memory is not limited to a nonvolatile memory, and may be a volatile memory such as an SRAM.

As described above, in the neural network devices 10 and 40, the power consumption is reduced by setting the write current to be smaller than the specified value, and therefore clock gating and power gating can be applied to further reduce the power consumption. For example, when the logic operation circuit 21 does not access the memory 22, supply of a clock to the memory 22 can be stopped or supply of power can be cut off. Of course, the clock gating and the power gating can also be performed on the logic operation circuit 21.

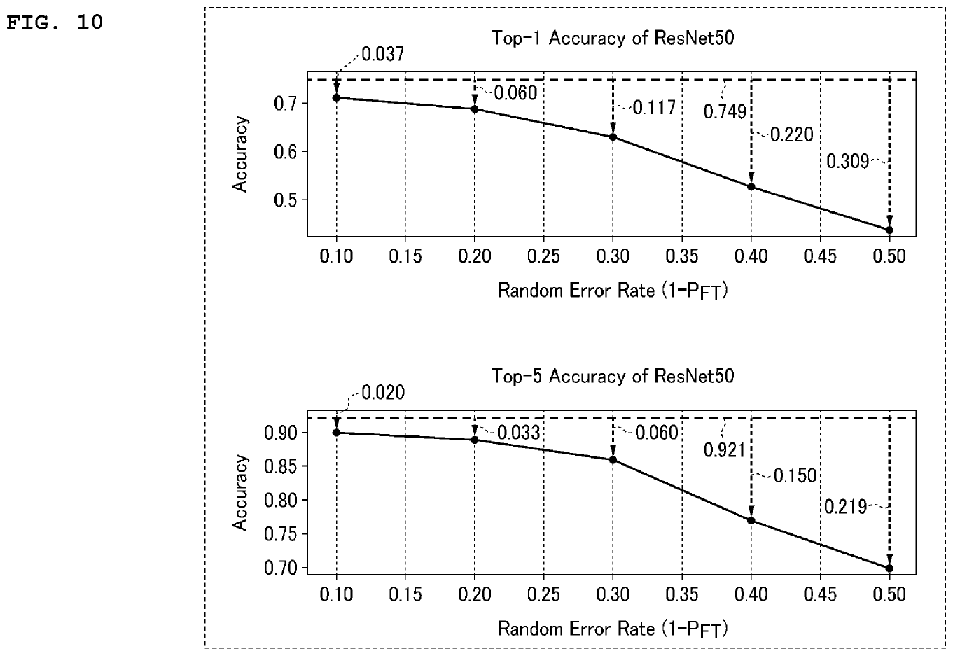

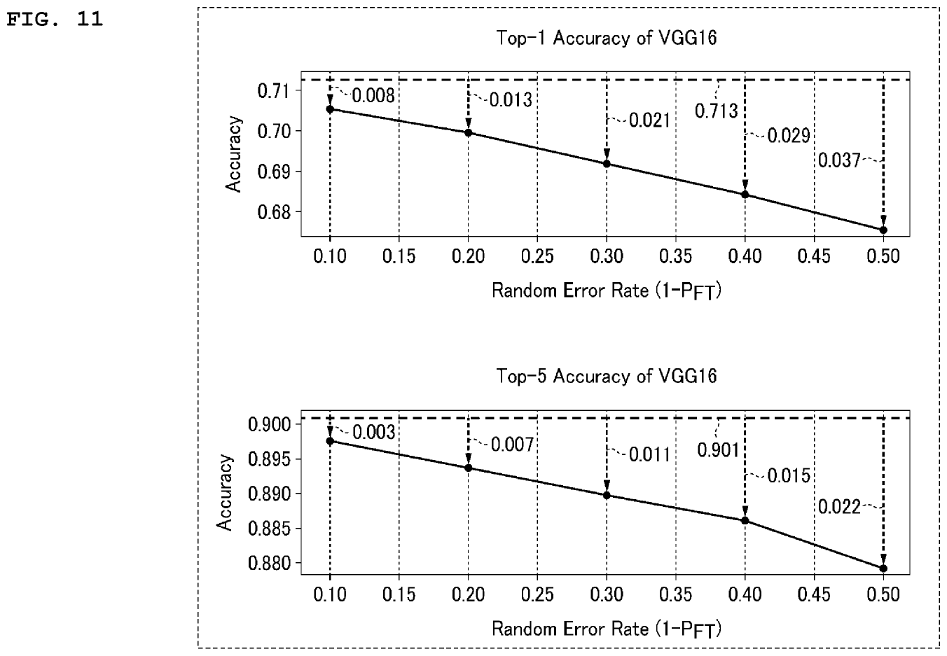

Using neural network models ResNet50 and VGG16 which are convolutional neural networks, a simulation was performed assuming a case in which a write current or voltage to a memory cell that constitutes a neural network device is set to be smaller than a specified value, and an influence of an error bit of operation data on recognition accuracy was verified. In this verification, assuming that the write current to the memory cell is smaller than the specified value, an error is randomly imparted to lower 8 bits of a filter weight in a convolution operation at a ratio of 10% to 20% (the effective bit ratio P_{FT} is 0.9 to 0.8). Further, the recognition was evaluated using Top-1 accuracy and Top-5 accuracy. The results are illustrated in FIGS. 10 and 11. In each of graphs illustrated in FIGS. 10 and 11, the horizontal axis represents a random error rate (1−P_{FT}), and the vertical axis represents a recognition accuracy.

A decrease in recognition accuracy from a standard recognition accuracy when an error is impacted is as follows. For ResNet50, with a 10% error, the Top-1 accuracy was 0.037 and the Top-5 accuracy was 0.020, and with a 20% error, the Top-1 accuracy was 0.060 and the Top-5 accuracy was 0.033. For VGG16, with a 10% error, the Top-1 accuracy was 0.008 and the Top-5 accuracy was 0.003, and with a 20% error, the Top-1 accuracy was 0.013 and the Top-5 accuracy was 0.007. As described above, it can be seen that applying an error at a ratio of 10% to 20% has almost no influence on recognition accuracy. From this result, it can be seen that the power consumption can be reduced by making the write current or voltage to the memory cell that constitutes the neural network device smaller than the specified value with almost no influence on the recognition accuracy. A standard recognition accuracy when no error is imparted is as follows. For ResNet50, the Top-1 accuracy was 0.749 and the Top-5 accuracy was 0.921. For VGG16, the Top-1 accuracy was 0.713 and the Top-5 accuracy was 0.901.

Although an example in which an operating condition determination unit is provided in a neural network device has been described above, the operating condition determination unit may be an independent operating condition determination device, and may be configured to be connected to a processor and a power supply unit when a set value of a write current or a write voltage is determined.

### REFERENCE SIGN LIST

10, 40 neural network device
12 processor
14 power supply unit
16 operating condition determination unit
21 logic operation circuit
22 memory
24 memory cell
25 MTJ element
32 output control circuit

1. A neural network device comprising:
a neural network operation unit including a memory that includes a plurality of memory cells and that holds operation data for neural network processing, and an operation circuit that transmits and receives the operation data to and from the memory and that performs operation in the neural network processing using the operation data; and
a power supply unit configured to supply, to the memory when the operation data is written, a write current or a write voltage having a set value at which a processing accuracy of the neural network processing by the neural network operation unit is equal to or greater than a set accuracy and that is set to be smaller than a specified value determined to switch bits for the plurality of memory cells.

2. The neural network device according to claim 1, further comprising:
an operating condition determination unit configured to cause the neural network operation unit to operate and configured to determine the set value, wherein
the power supply unit supplies, to the memory, the write current or the write voltage having the set value determined by the operating condition determination unit.

3. The neural network device according to claim 2, wherein
a ratio of the number of effective bits of the operation data, from which an error bit is excluded, to a total number of bits of the operation data in one neural network processing is defined as an effective bit ratio, and
the operating condition determination unit
identifies an effective bit ratio at which a processing accuracy for a test dataset is equal to or greater than the set accuracy by imparting an error to a part of the operation data for the test dataset and causing the neural network operation unit to execute the test dataset, and
determines the identified effective bit ratio as a switching probability at which values of bits in the memory cells are switched, and determines, based on characteristics of the memory cells, the write current or the write voltage for the memory cells corresponding to the switching probability as the set value.

4. The neural network device according to claim 3, wherein
the operating condition determination unit stepwisely changes the number of error bits in the operation data for each test data in the test dataset for each neural network processing on the test dataset, and obtains the identified effective bit ratio based on a maximum number of error bits at which a processing accuracy, obtained by causing the neural network operation unit to execute the neural network processing a plurality of times on the test dataset, is equal to or greater than the set accuracy.

5. The neural network device according to claim 2, wherein
the operating condition determination unit determines the set value at which a processing accuracy for a test dataset is equal to or greater than the set accuracy by making the write current or the write voltage supplied to the memory from the power supply unit smaller than the specified value and causing the neural network operation unit to operate.

6. The neural network device according to claim 5, wherein
the operating condition determination unit stepwisely changes the write current or the write voltage supplied from the power supply unit for each neural network processing on the test dataset, and sets, as the set value, a minimum write current or write voltage at which a processing accuracy, obtained by causing the neural network operation unit to execute the neural network processing a plurality of times on the test dataset, is equal to or greater than the set accuracy.

7. The neural network device according to any one of claims 1 to 6, wherein
the memory is one of STT-MRAM, SOT-MRAM, ReRAM, and SRAM.

8. An operating condition determination method comprising:
an accuracy setting step of setting, as a set accuracy, a processing accuracy to be satisfied by a neural network operation unit including a memory that includes a plurality of memory cells and that holds operation data for neural network processing, and an operation circuit that transmits and receives the operation data to and from the memory and that performs operation in the neural network processing using the operation data; and
a determination step of determining, for a write current or a write voltage supplied to the memory when the operation data is written to the memory, a set value that satisfies the set accuracy and is set to be smaller than a specified value determined to switch bits for the plurality of memory cells.

9. The operating condition determination method according to claim 8, wherein
a ratio of the number of effective bits of the operation data, from which an error bit is excluded, to a total number of bits of the operation data in one neural network processing is defined as an effective bit ratio, and
the determination step includes
an identification step of identifying an effective bit ratio at which a processing accuracy for a test dataset is equal to or greater than the set accuracy by imparting an error to a part of the operation data for the test dataset and causing the neural network operation unit to execute the test dataset, and
a conversion step of setting the identified effective bit ratio as a switching probability at which values of bits in the memory cells are switched, and setting, based on characteristics of the memory cells, the write current or the write voltage for the memory cells corresponding to the switching probability as the set value.

10. The operating condition determination method according to claim 9, wherein
in the identification step, the number of error bits in the operation data for each test data in the test dataset is stepwisely changed for each neural network processing on the test dataset, a maximum number of error bits at which a processing accuracy, obtained by causing the neural network operation unit to execute the neural network processing a plurality of times on the test dataset, is equal to or greater than the set accuracy is obtained, and the identified effective bit ratio is obtained based on the obtained number of error bits.

11. The operating condition determination method according to claim 8, wherein
in the determination step, the set value at which a processing accuracy for a test dataset is equal to or greater than the set accuracy is determined by making the write current or the write voltage supplied to the memory smaller than the specified value and causing the neural network operation unit to operate.

12. The operating condition determination method according to claim 11, wherein
in the determination step, the write current or the write voltage is stepwisely changed for each neural network processing on the test dataset, and a minimum write current or write voltage at which a processing accuracy, obtained by causing the neural network operation unit to execute the neural network processing a plurality of times on the test dataset, is equal to or greater than the set accuracy, is set as the set value.
